(19) United States
(12) Patent Application Publication
(10) Pub. No.: US 2025/0295002 A1
(43) Pub. Date: Sep. 18, 2025

(54) ORGANIC LIGHT-EMITTING DEVICE AND METHOD FOR MANUFACTURING THE SAME

(71) Applicant: CANON KABUSHIKI KAISHA, Tokyo (JP)

(72) Inventor: RYUJI ISHII, Kanagawa (JP)

(21) Appl. No.: 19/077,626

(22) Filed: Mar. 12, 2025

(30) Foreign Application Priority Data
Mar. 13, 2024 (JP) 2024-038937

(51) Int. Cl. H10K 59/80; H10K 59/12; H10K 59/65

(52) U.S. Cl. CPC H10K 59/8722; H10K 59/1201; H10K 59/65

(57) ABSTRACT

The present disclosure provides a method for manufacturing an organic light-emitting device, the method including an organic light-emitting element forming step of forming a plurality of organic light-emitting elements on a substrate, a first sealing layer forming step of forming a first sealing layer covering the organic light-emitting elements and having a groove in a non-display region, and a second sealing layer forming step of forming a second sealing layer on the first sealing layer using a shadow mask, wherein the second sealing layer forming step is a step of forming the second sealing layer in a state where an edge portion constituting a periphery of an opening of the shadow mask is disposed so as to be located on the groove.

### BACKGROUND OF THE INVENTION

### Field of the Invention

The present disclosure relates to an organic light-emitting device and a method for manufacturing the organic light-emitting device.

### Description of the Related Art

Organic light-emitting devices such as organic EL displays are required to realize a larger display region in the same casing (bezel or cabinet) size or realize a reduction in the size of the main body while the display size is maintained, and are required to narrow a frame in a sealing region around the display region.

Japanese Translation Patent Publication No. 2014-520371 (translation of PCT/US2012/042988) discloses, as a technique of narrowing a frame in a sealing region around a display region, a method for patterning a sealing layer with a shadow mask.

A sealing layer can include a highly water-resistant layer that prevents moisture from entering from the outside; however, in such a layer with high water resistance, cracks may be formed by a foreign substance or a difference in the level, as illustrated in FIG. 6. An organic light-emitting device in FIG. 6 includes a substrate 1, a pixel isolation film 2, an organic light-emitting element 6, and a sealing layer 7 that covers and protects the organic light-emitting element 6. Here, the organic light-emitting element 6 is an element having a lower electrode 3, an organic compound layer 4, and an upper electrode 5 in this order. The sealing layer 7 with high water resistance is formed so as to cover the organic light-emitting element 6. Cracks 32 may be formed in the sealing layer 7 by the difference in the level due to the pixel isolation film 2 or a foreign substance 31. In view of this, a layer with high coverage characteristics for smoothing the cracks 32 can be included. Furthermore, since such a layer with high coverage characteristics may have high moisture permeability, a sealing layer with high water resistance can be stacked on the layer with high coverage characteristics to cover the top and an edge portion of the layer with high coverage characteristics.

When a sealing layer is patterned with a shadow mask as in PCT Japanese Translation Patent Publication No. 2014-520371 in order to form a layer with high coverage characteristics, as illustrated in FIGS. 7A and 7B, a foreign substance or a flaw is generated in a portion where a base and the shadow mask are in contact with each other. As illustrated in FIG. 7A, when a sealing layer 8 with high coverage characteristics is formed on a sealing layer 7 with high water resistance by patterning using a shadow mask 20, a foreign substance 31 due to a flaw is generated on the sealing layer 7 and the sealing layer 8 by the edge of the shadow mask 20. Subsequently, as illustrated in FIG. 7B, when a sealing layer 9 with high water resistance is stacked on the sealing layer 7 and the sealing layer 8, there may be a disadvantage in that moisture enters from cracks 32 at the periphery of the foreign substance 31 due to the flaw, and the entered water reaches a device as a result of lateral permeation 33, resulting in corrosion.

When the contact between the shadow mask and the base is avoided by, for example, floating the shadow mask with a rib, there is a disadvantage in that the sealing layer extends in a blurring manner and narrowing the frame in the sealing region around the display region cannot be achieved.

### SUMMARY OF THE INVENTION

The present disclosure provides an organic light-emitting device that has good water resistance and that can have a narrow frame and a method for manufacturing the organic light-emitting device.

A method for manufacturing an organic light-emitting device according to an aspect of the present disclosure includes
an organic light-emitting element forming step of forming a plurality of organic light-emitting elements on a substrate;
a first sealing layer forming step of forming a first sealing layer covering the organic light-emitting elements and having a groove in a non-display region; and
a second sealing layer forming step of forming a second sealing layer on the first sealing layer using a shadow mask,
wherein the second sealing layer forming step is a step of forming the second sealing layer in a state where an edge portion constituting a periphery of an opening of the shadow mask is disposed so as to be located on the groove.

An organic light-emitting device according to another aspect of the present disclosure includes
a substrate; a plurality of organic light-emitting elements; and a sealing layer covering the organic light-emitting elements, the organic light-emitting elements and the sealing layer being disposed on the substrate,
wherein the sealing layer includes a first sealing layer and a second sealing layer covering the first sealing layer,
the first sealing layer has a groove in a non-display region, and
an edge portion of the second sealing layer is formed on an inner portion of the groove.

Further features of the present disclosure will become apparent from the following description of exemplary embodiments with reference to the attached drawings.

### BRIEF DESCRIPTION OF THE DRAWINGS

FIGS. 1A and 1B are schematic views illustrating an example of an organic light-emitting device according to the present disclosure.

FIGS. 2A and 2B are partial enlarged views of portion IIA, IIB of FIG. 1A.

FIGS. 3A to 3G are schematic sectional views each illustrating an example of the shape of a groove of a substrate.

FIGS. 4A to 4D are schematic sectional views illustrating an example of a method for manufacturing an organic light-emitting device according to the present disclosure.

FIG. 5 is a plan view illustrating an example of a shadow mask.

FIG. 6 is a schematic sectional view illustrating a situation in which cracking occurs in a sealing layer due to a foreign substance or a difference in the level.

FIGS. 7A and 7B are schematic sectional views illustrating a situation in which a foreign substance or a flaw is generated in a portion in contact with a shadow mask.

FIG. 8 is a schematic view illustrating an example of a display apparatus according to an embodiment of the present disclosure.

FIG. 9A is a schematic view illustrating an example of an imaging apparatus according to an embodiment of the present disclosure, and FIG. 9B is a schematic view illustrating an example of an electronic apparatus according to an embodiment of the present disclosure.

FIG. 10A is a schematic view illustrating an example of a display apparatus according to an embodiment of the present disclosure, and FIG. 10B is a schematic view illustrating an example of a foldable display apparatus.

FIG. 11A is a schematic view illustrating an example of an illumination apparatus according to an embodiment of the present disclosure, and FIG. 11B is a schematic view illustrating an example of a moving object including a vehicle lighting fixture according to an embodiment of the present disclosure.

FIG. 12A is a schematic view illustrating an example of a wearable device according to an embodiment of the present disclosure, and FIG. 12B is a schematic view illustrating another example of the wearable device according to an embodiment of the present disclosure.

FIG. 13A is a schematic diagram illustrating an example of an image forming apparatus according to an embodiment of the present disclosure, and FIGS. 13B and 13C are schematic views each illustrating an example of an exposure light source for an image forming apparatus according to an embodiment of the present disclosure.

### DESCRIPTION OF THE EMBODIMENTS

Hereinafter, an organic light-emitting device and a method for manufacturing the organic light-emitting device according to embodiments of the present disclosure will be described. The present disclosure is not limited to these embodiments.

### Organic Light-Emitting Device

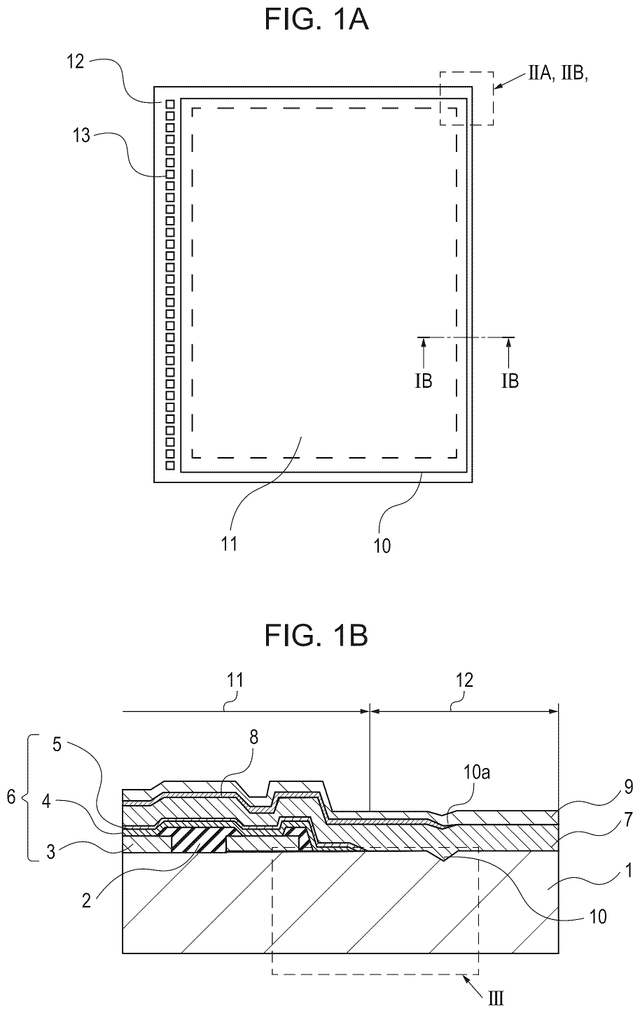

First, an organic light-emitting device according to embodiments of the present disclosure will be described with reference to the drawings. FIGS. 1A and 1B are schematic views illustrating an example of an organic light-emitting device according to the present disclosure. FIG. 1A is a plan view, and FIG. 1B is a sectional view taken along line IB-IB in FIG. 1A. In FIGS. 1A and 1B, reference numeral 1 denotes a substrate, reference numeral 2 denotes a pixel isolation film, reference numeral 3 denotes a lower electrode, reference numeral 4 denotes an organic compound layer, reference numeral 5 denotes an upper electrode, reference numeral 6 denotes an organic light-emitting element, reference numeral 7 denotes a first sealing layer, reference numeral 8 denotes a second sealing layer, reference numeral 9 denotes a third sealing layer, reference numerals 10 and 10a each denote a groove, reference numeral 11 denotes a display region, reference numeral 12 denotes a non-display region, and reference numeral 13 denotes a pad electrode. For the sake of convenience of illustration, in FIG. 1A, illustration of components other than the groove 10, the display region 11, the non-display region 12, and the pad electrodes 13 is omitted.

The organic light-emitting device illustrated in FIGS. 1A and 1B has a display region 11 and a non-display region 12 outside the display region 11 and has a plurality of pad electrodes 13 in the non-display region 12, as illustrated in FIG. 1A. The organic light-emitting device illustrated in FIGS. 1A and 1B has, in the non-display region 12 of the substrate 1, a groove 10 along the periphery of the display region 11.

As illustrated in FIG. 1B, the organic light-emitting device illustrated in FIGS. 1A and 1B includes a plurality of organic light-emitting elements 6 in the display region 11 on the substrate 1. In FIGS. 1A and 1B, the organic light-emitting elements 6 are each an element that includes a lower electrode 3, an organic compound layer 4, and an upper electrode 5 in this order, and a pixel isolation film 2 is provided between adjacent organic light-emitting elements 6. One of the lower electrode 3 and the upper electrode 5 may be a positive electrode, and the other may be a negative electrode. The emission color of each organic light-emitting element 6 may be red, green, blue, or white.

The substrate 1 may be transparent or opaque. The substrate 1 may be, for example, an insulating substrate composed of silicon, glass, a synthetic resin, or the like, or a conductive substrate or semiconductor substrate in which an insulating layer composed of silicon oxide, silicon nitride, or the like is formed on the surface.

The pixel isolation film 2 is an insulating layer and is also referred to as a bank. The pixel isolation film 2 covers the ends of the lower electrode 3 and is disposed so as to surround the lower electrode 3. A portion of the lower electrode 3 not covered with the pixel isolation film 2 is in contact with the organic compound layer 4 and serves as a light-emitting region.

Examples of the material constituting the lower electrode 3 include a compound of aluminum and silicon, aluminum, silver, indium tin oxide (ITO), indium zinc oxide (IZO), and titanium.

The specific structure of the organic compound layer 4 may be, for example, a three-layer structure composed of a hole transport layer, a light-emitting layer, and an electron transport layer. However, the structure is not limited to this three-layer structure and may be a single-layer structure composed only of a light-emitting layer, or a layer structure of a plurality of layers other than the three-layer structure (such as a two-layer structure or a four-layer structure).

Examples of the material constituting the upper electrode 5 include transparent conductive oxide films composed of indium zinc oxide (IZO) or indium tin oxide (ITO) and metal semi-transparent films composed of silver, aluminum, gold, magnesium-silver (MgAg), or the like.

The organic light-emitting device illustrated in FIGS. 1A and 1B includes a sealing layer that covers and protects the organic light-emitting elements 6 as illustrated in FIG. 1B. In FIGS. 1A and 1B, the sealing layer has a three-layer structure of a first sealing layer 7, a second sealing layer 8, and a third sealing layer 9 but may have a two-layer structure of the first sealing layer 7 and the second sealing layer 8. A color filter, a microlens, etc. may be provided on the sealing layer. When the color filter is provided, a planarization layer may be provided between the color filter and the sealing layer. The planarization layer may be composed of, for example, an acrylic resin. The same applies when a planarization layer is provided between the color filter and the microlens.

In FIGS. 1A and 1B, the first sealing layer 7 covers the organic light-emitting elements 6 and is formed over the entire surface of the substrate 1 except for regions where the pad electrodes 13 are formed. As illustrated in FIG. 1B, the first sealing layer 7 has, at a position corresponding to the groove 10 of the substrate 1, a groove 10a serving as a concave portion conforming to the groove 10. The first sealing layer 7 may be a layer with high water resistance, and a moisture permeation rate of the first sealing layer 7 can be 10⁻⁵ g/m²/day or less. The moisture permeation rate of the first sealing layer 7 can be 10⁻⁵ g/m²/day or less and 10⁻⁸ g/m²/day or more, or 10⁻⁵ g/m²/day or less and 10⁻⁶ g/m²/day or more. Examples of the material constituting the first sealing layer 7 include silicon nitride, silicon oxide, and silicon oxynitride. The first sealing layer 7 may contain at least one selected from the group consisting of silicon nitride, silicon oxide, and silicon oxynitride. The first sealing layer 7 can be formed by, for example, a sputtering method, a CVD method, or an ALD method. The thickness of the first sealing layer 7 can be 50 nm or more, or 100 nm or more and 2,000 nm or less. When the thickness of the first sealing layer 7 is 2,000 nm less, film peeling is less likely to occur.

In FIGS. 1A and 1B, the second sealing layer 8 is formed on an inner portion of the groove 10a and inside the groove 10a on the first sealing layer 7. As illustrated in FIG. 1B, an edge portion of the second sealing layer 8 is formed on the inner portion of the groove 10a of the first sealing layer 7. The second sealing layer 8 may be a layer with high coverage characteristics and may have conformality (characteristic of being formed as a uniform film along the surface) for a structure having a high aspect ratio. The second sealing layer 8 may be a layer that can be conformally deposited in a structure having an aspect ratio of higher than 1/10. The second sealing layer 8 can be a layer that can be conformally deposited in a structure having an aspect ratio in a range of higher than 1/10 and 1/4,000 or less. The second sealing layer 8 can be a layer that can be conformally deposited in a structure having an aspect ratio in a range of higher than 1/10 and 1/1,000 or less. Examples of the material constituting the second sealing layer 8 include hexamethyldisiloxane (HMDSO), dimethylsiloxane (DMSO), aluminum oxide, hafnium oxide, zirconium oxide, and titanium oxide. The second sealing layer 8 may be a stacked film composed of a combination of these materials. The second sealing layer 8 may contain at least one selected from the group consisting of hexamethyldisiloxane, dimethylsiloxane, aluminum oxide, hafnium oxide, zirconium oxide, and titanium oxide. The second sealing layer 8 can be formed by, for example, a CVD method or an ALD method. The thickness of the second sealing layer 8 can be 5 nm or more, or 10 nm or more and 200 nm or less. When the thickness of the second sealing layer 8 is 200 nm less, film peeling is less likely to occur.

In FIGS. 1A and 1B, the third sealing layer 9 covers the first sealing layer 7 and the second sealing layer 8 and is formed over the entire surface of the substrate 1 except for regions where the pad electrodes 13 are formed. As illustrated in FIG. 1B, the third sealing layer 9 may have a concave portion at a position corresponding to the groove 10 of the substrate 1. The third sealing layer 9 may be a layer with high water resistance, and a moisture permeation rate of the third sealing layer 9 can be 10⁻⁵ g/m²/day or less. The moisture permeation rate of the third sealing layer 9 can be 10⁻⁵ g/m²/day or less and 10⁻⁸ g/m²/day or more, or can be 105 g/m²/day or less and 10⁻⁶ g/m²/day or more. Examples of the material constituting the third sealing layer 9 include silicon nitride, silicon oxide, and silicon oxynitride. The third sealing layer 9 may contain at least one selected from the group consisting of silicon nitride, silicon oxide, and silicon oxynitride. The third sealing layer 9 can be formed by, for example, a sputtering method, a CVD method, or an ALD method. The thickness of the third sealing layer 9 can be 50 nm or more, or 100 nm or more and 2,000 nm or less. When the thickness of the third sealing layer 9 is 2,000 nm less, film peeling is less likely to occur.

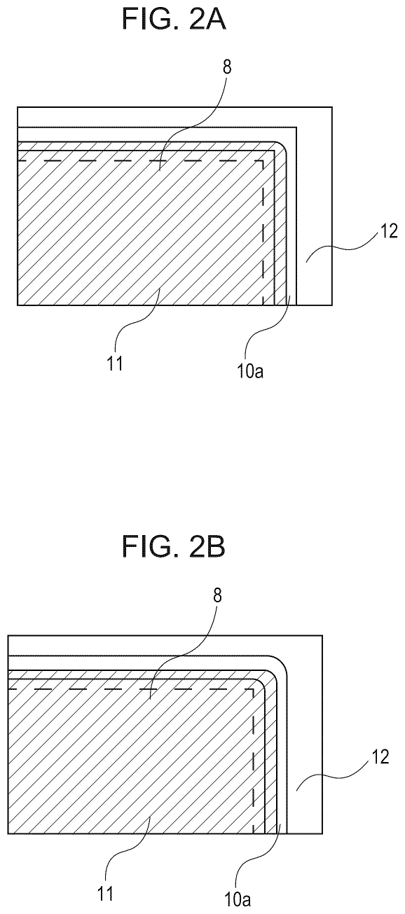

FIGS. 2A and 2B are partial enlarged views of portion IIA, IIB of FIG. 1A. For the sake of convenience of illustration, in FIGS. 2A and 2B, illustration of components other than the second sealing layer 8, the groove 10a, the display region 11, and the non-display region 12 is omitted. As illustrated in FIG. 2A, also in a corner portion, the edge portion of the second sealing layer 8 may be formed on the inner portion of the groove 10a. As illustrated in FIG. 2B, in the case where a corner portion is rounded, the edge portion of the second sealing layer 8 may have a shape that conforms, in the inner portion of the groove 10a, to the roundness of the corner portion.

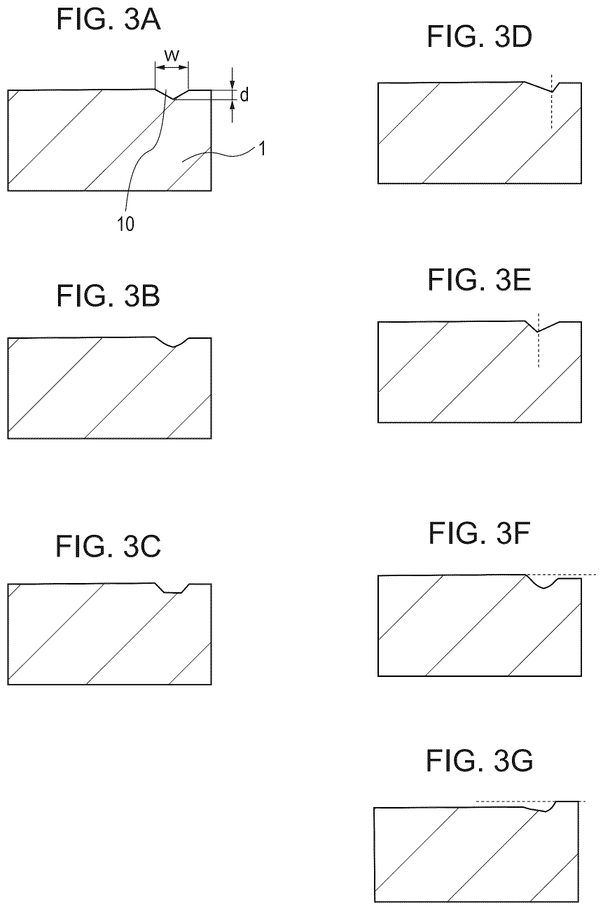

FIGS. 3A to 3G are schematic sectional views each illustrating an example of the shape of the groove of the substrate and are views illustrating a part of the substrate corresponding to portion III in FIG. 1B. The cross-sectional shape of the groove 10 is not particularly limited, and may be a V-shape as illustrated in FIG. 3A, a U-shape as illustrated in FIG. 3B, or a trapezoidal shape as illustrated in FIG. 3C. As illustrated in FIGS. 3D and 3E, the cross-sectional shape of the groove 10 may be a shape in which the position of the deepest portion of the groove 10 is shifted from the position of the center of the groove 10 in a width w direction to the edge portion side (on the right side of the drawing) of the substrate 1 or the display region 11 side (on the left side of the drawing) of the substrate 1. As illustrated in FIGS. 3F and 3G, the cross-sectional shape of the groove 10 may be a shape in which the height from the deepest portion is different between the edge portion side of the substrate 1 and the display region 11 side of the substrate 1.

### Method for Manufacturing Organic Light-Emitting Device

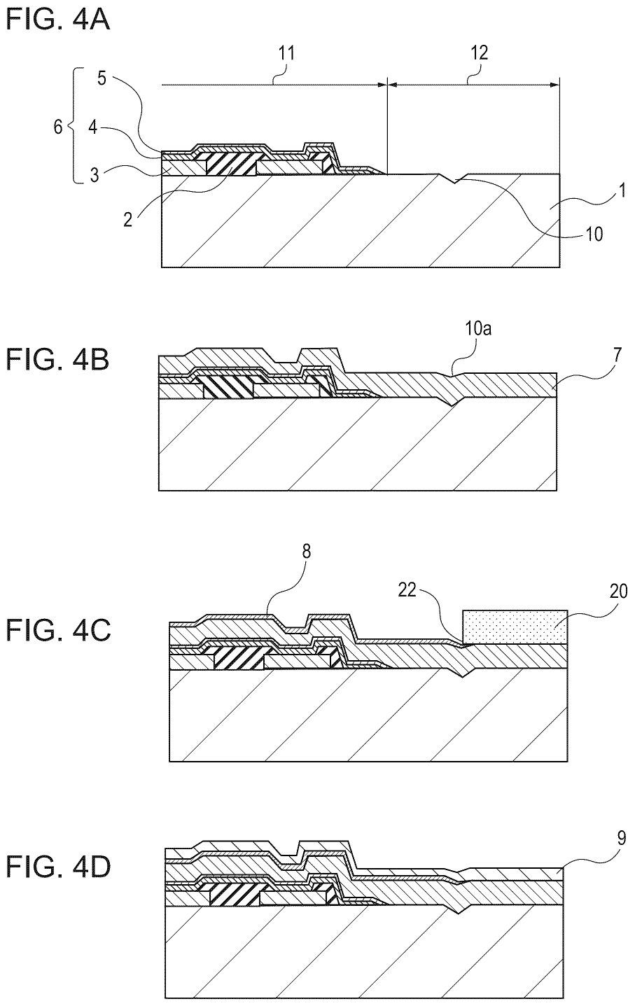

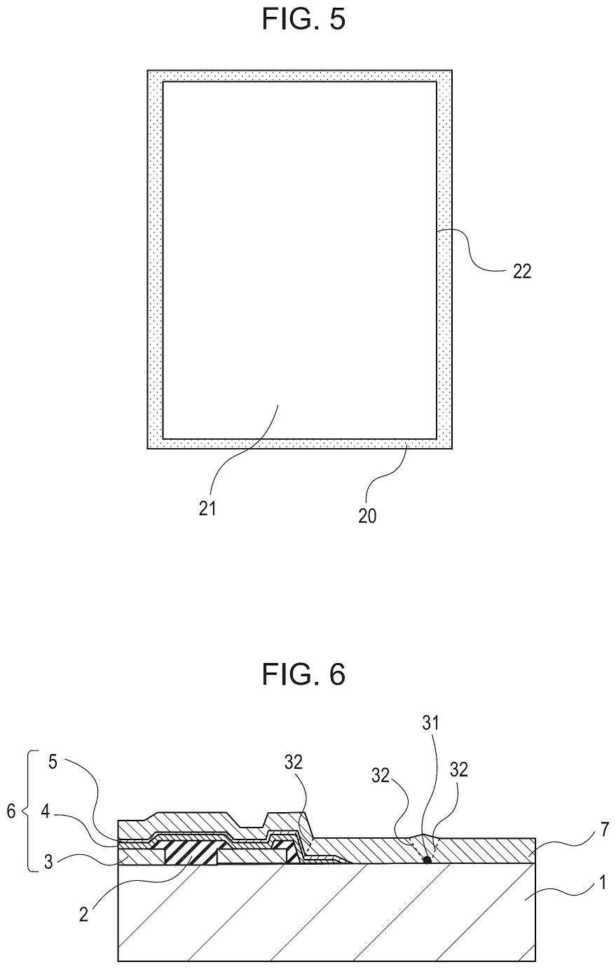

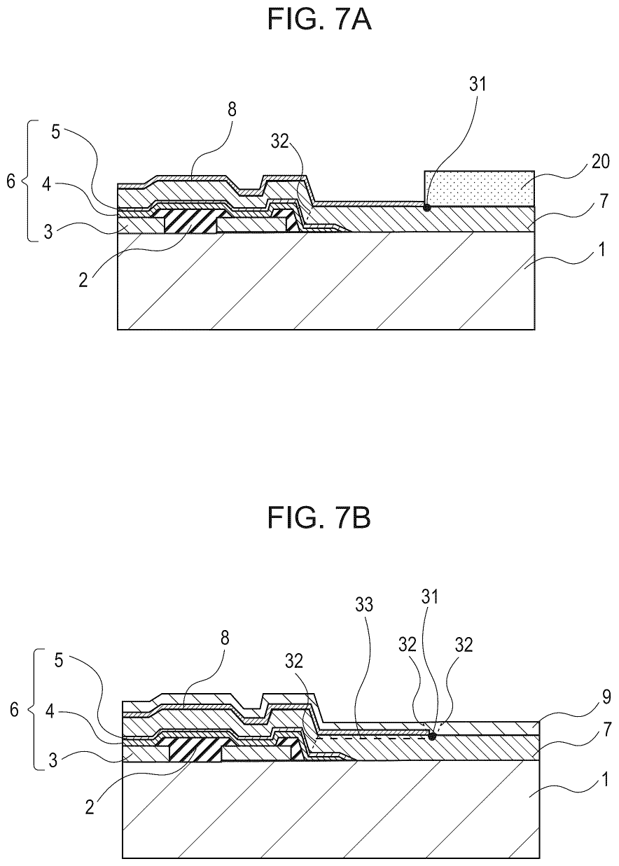

FIGS. 4A to 4D are schematic sectional views illustrating an example of a method for manufacturing an organic light-emitting device according to the present disclosure. FIG. 5 is a plan view illustrating an example of a shadow mask used in the present disclosure. The method for manufacturing an organic light-emitting device according to the present disclosure may include a pad electrode extraction step of removing a sealing layer in a region where the pad electrodes 13 are formed.

### Substrate Groove Forming Step

As illustrated in FIG. 4A, first, a groove 10 is formed in a non-display region 12 of a substrate 1, which can be along the periphery of a display region 11. The method of forming the groove 10 is not particularly limited, and the groove 10 can be formed by, for example, photolithography using a gray scale mask. Note that the substrate groove forming step is not essential.

### Organic Light-Emitting Element Forming Step

Next, as illustrated in FIG. 4A, a lower electrode 3, a pixel isolation film 2, an organic compound layer 4, and an upper electrode 5 are formed on the substrate 1 in this order to form a plurality of organic light-emitting elements 6 in the display region 11.

### First Sealing Layer Forming Step

Next, as illustrated in FIG. 4B, a first sealing layer 7 covering the organic light-emitting elements 6 is formed over the entire surface of the substrate 1. As illustrated in FIG. 4B, in the first sealing layer 7, a groove 10a is formed as a concave portion conforming to the groove 10 at a position corresponding to the groove 10 of the substrate 1. The first sealing layer 7 can be formed by, for example, a sputtering method, a CVD method, or an ALD method. When the method does not include the substrate groove forming step, the groove 10a may be formed in the non-display region of the first sealing layer 7, which can be along the periphery of the display region 11 by a publicly known method such as etching.

### Second Sealing Layer Forming Step

Next, as illustrated in FIG. 4C, a second sealing layer 8 is formed on the first sealing layer 7 by patterning using a shadow mask 20. For example, a shadow mask illustrated in FIG. 5 can be used as the shadow mask 20. The shadow mask 20 illustrated in FIG. 5 has a rectangular opening 21. In FIG. 5, an edge portion 22 constitutes the periphery of the opening 21.

As illustrated in FIG. 4C, the shadow mask 20 is disposed such that the edge portion 22 constituting the periphery of the opening 21 is located on the groove 10a of the first sealing layer 7. Subsequently, the second sealing layer 8 is formed in the opening 21 of the shadow mask 20. As a result, an edge portion of the second sealing layer 8 is formed on an inner portion of the groove 10a of the first sealing layer 7. The second sealing layer 8 can be formed by, for example, a CVD method or an ALD method.

### Third Sealing Layer Forming Step

Next, as illustrated in FIG. 4D, after the shadow mask 20 is removed, a third sealing layer 9 is formed over the entire surface of the substrate 1 so as to cover the first sealing layer 7 and the second sealing layer 8. As illustrated in FIG. 4D, a concave portion may be formed in the third sealing layer 9 at a position corresponding to the groove 10 of the substrate 1. The third sealing layer 9 can be formed by, for example, a sputtering method, a CVD method, or an ALD method. Note that the formation of the third sealing layer 9 is not essential.

As described above, since the groove 10 is provided in the substrate 1, even when the shadow mask 20 closely adheres, the edge portion 22 constituting the periphery of the opening 21 of the shadow mask 20 is not in contact with the base, and a foreign substance due to a flaw is not generated on the first sealing layer 7 and the edge portion of the second sealing layer 8. Thus, a layer with no cracks can be formed as the third sealing layer 9. Furthermore, unlike the case where the contact between the shadow mask and the base is avoided by, for example, floating the shadow mask with a rib, extension of the second sealing layer 8 in a blurring manner does not occur.

Accordingly, the film edge of the second sealing layer 8 is enclosed inside the third sealing layer 9 with a minimum area, and thus stacked sealing layers that have high water resistance and that prevent moisture from entering from the outside can be formed. Furthermore, the frame can be narrowed in the sealing region around the display region by causing the shadow mask 20 to closely adhere, compared with the case where the contact between the shadow mask and the base is avoided by, for example, floating the shadow mask with a rib. Thus, it is possible to provide a high value-added organic light-emitting device such as an organic EL (electroluminescence) display.

### Applications of Organic Light-Emitting Device

The organic light-emitting device according to the present embodiment can be used as a constituent member of a display apparatus or an illumination apparatus. In addition, the organic light-emitting device is used in, for example, an exposure light source of an electrophotographic image forming apparatus, a backlight of a liquid crystal display apparatus, and a light-emitting apparatus including a color filter on a white light source.

The display apparatus may be an image information processing apparatus that includes an image input unit to which image information is input from an area CCD, a linear CCD, a memory card, or the like and an information processing unit configured to process the input information and that displays an input image on a display unit. The display apparatus may include the organic light-emitting device of the present embodiment. The organic light-emitting device may have a plurality of pixels, and at least one of the plurality of pixels may include an organic light-emitting element and an active element, such as a transistor, connected to the organic light-emitting element. In this case, the substrate may be a semiconductor substrate composed of, for example, silicon, and the transistor may be a MOSFET formed on the substrate. An image display apparatus includes an input unit configured to input image information and a display unit configured to output an image, and the display unit includes the display apparatus of the present embodiment.

The display unit included in an imaging apparatus or an ink jet printer may have a touch panel function. The touch panel function may be operated by using infrared radiation, an electrostatic capacitance, a resistive film, or electromagnetic induction, and the operation method is not particularly limited. The display apparatus may be used in a display unit of a multifunctional printer.

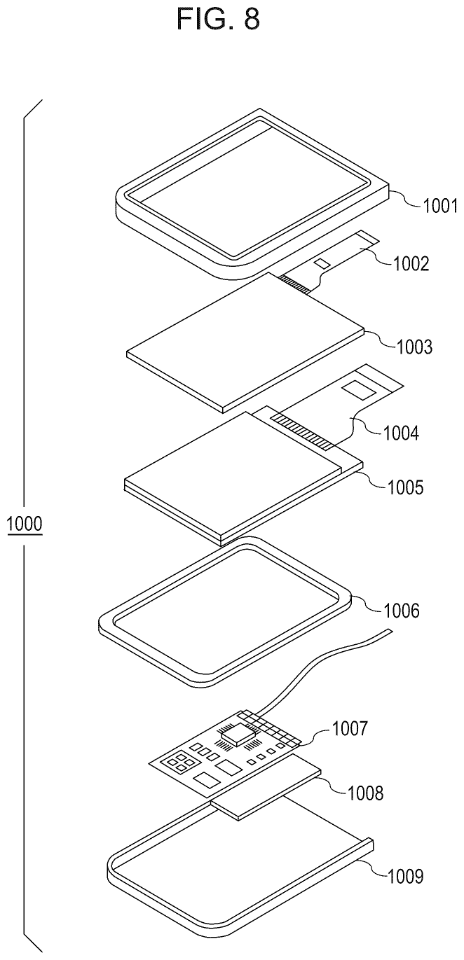

FIG. 8 is a schematic view illustrating an example of the display apparatus according to the present embodiment. A display apparatus 1000 may include an upper cover 1001 and a lower cover 1009, and a touch panel 1003, a display panel 1005, a frame 1006, a circuit substrate 1007, and a battery 1008 that are disposed between the upper cover 1001 and the lower cover 1009. The touch panel 1003 and the display panel 1005 are connected to flexible printed circuits FPC 1002 and 1004, respectively. Transistors are printed on the circuit substrate 1007. The battery 1008 is not necessarily installed unless the display apparatus is a portable apparatus or may be installed in a different position even if the display apparatus is a portable apparatus.

The display apparatus according to the present embodiment may include a color filter having red, green, and blue portions. The red, green, and blue portions of the color filter may be arranged in the delta pattern.

The display apparatus according to the present embodiment may be used in a display unit of a portable terminal. In such a case, the display apparatus may have both a display function and an operation function. Examples of the portable terminal include mobile phones such as smart phones, tablets, and head mount displays.

The display apparatus according to the present embodiment may be used in a display unit of an imaging apparatus including an optical unit including a plurality of lenses and an imaging device configured to receive light that has passed through the optical unit. The imaging apparatus may include a display unit configured to display information acquired by the imaging device. The display unit may be a display unit exposed to the outside of the imaging apparatus or a display unit disposed in a finder. The imaging apparatus may be a digital camera or a digital camcorder.

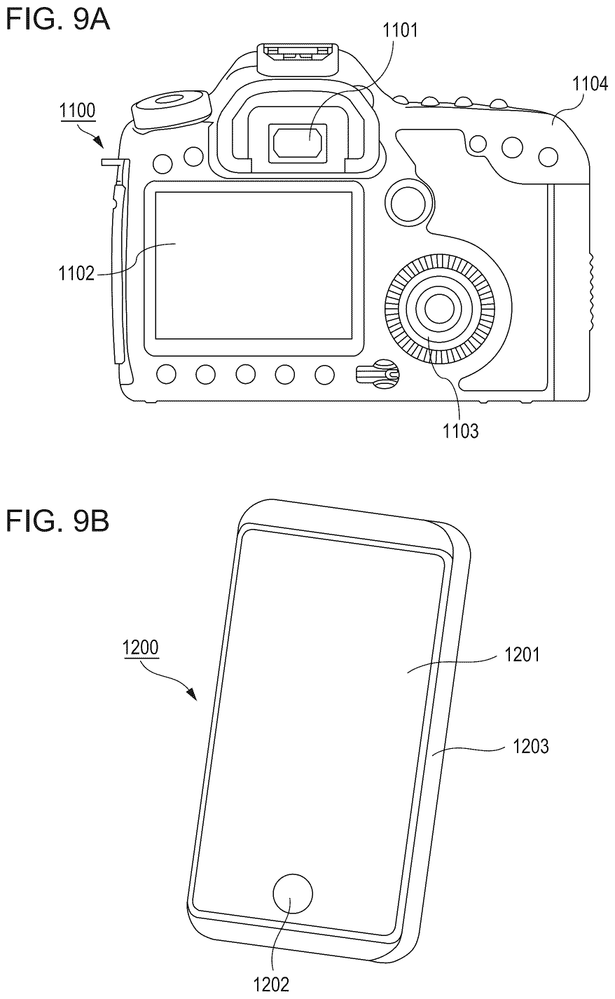

FIG. 9A is a schematic view illustrating an example of an imaging apparatus according to the present embodiment. An imaging apparatus 1100 may include a viewfinder 1101, a rear surface display 1102, an operation unit 1103, and a housing 1104. The viewfinder 1101 may include the display apparatus according to the present embodiment. In such a case, the display apparatus may display not only an image to be captured but also, for example, environmental information and imaging instructions. The environmental information may include, for example, the intensity of external light, the direction of external light, the moving speed of the photographic subject, and the possibility that the photographic subject may hide behind an obstacle.

Since the suitable timing for capturing an image is a very short period of time, it is desirable to display information as quickly as possible. Accordingly, a display apparatus including the organic light-emitting device of the present embodiment can be used. This is because organic light-emitting devices have a high response speed. Display apparatuses that use organic light-emitting devices can be more suitably used for such apparatuses required to have a high display speed than liquid crystal display apparatuses.

The imaging apparatus 1100 includes an optical unit not illustrated in the drawing. The optical unit includes a plurality of lenses and is configured to form an image on an imaging device contained in the housing 1104. By adjusting the relative positions of the plurality of lenses, the focal point can be adjusted. This operation can also be performed automatically. The imaging apparatus may also be referred to as a photoelectric conversion apparatus. The photoelectric conversion apparatus can employ, instead of a method of successively capturing images, image capturing methods such as a method of detecting a difference from the previous image and a method of extracting images from continuously recorded images.

FIG. 9B is a schematic view illustrating an example of an electronic apparatus according to the present embodiment. An electronic apparatus 1200 includes a display unit 1201, an operation unit 1202, and a housing 1203. The housing 1203 may include therein circuits, a printed circuit board having the circuits, a battery, and a communication unit. The display unit 1201 may include the organic light-emitting device according to the present embodiment. The operation unit 1202 may be a button or a touch panel-type responsive unit. The operation unit 1202 may be a biometric authentication unit configured to, for example, recognize the fingerprints and release the lock. The electronic apparatus that includes a communication unit can also be referred to as a communication apparatus. The electronic apparatus 1200 may include a lens and an imaging device so as to further have a camera function. An image captured by the camera function is displayed on the display unit 1201. Examples of the electronic apparatus 1200 include smart phones and notebook computers.

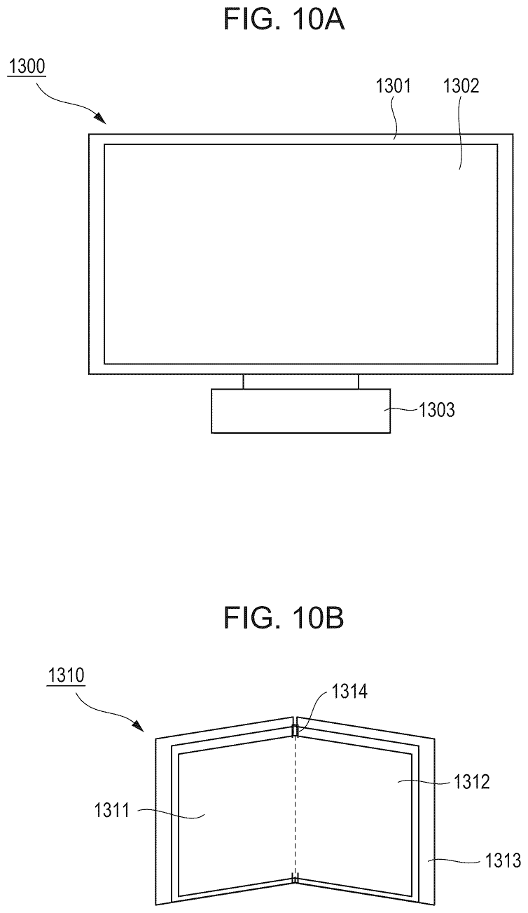

FIGS. 10A and 10B are schematic views each illustrating an example of the display apparatus according to the present embodiment. FIG. 10A illustrates a display apparatus such as a television monitor or a PC monitor. A display apparatus 1300 includes a frame 1301 and a display unit 1302. The light-emitting device according to the present embodiment may be used in the display unit 1302. The display apparatus 1300 incudes a base 1303 that supports the frame 1301 and the display unit 1302. The base 1303 is not limited to the form illustrated in FIG. 10A. The lower side of the frame 1301 may also function as the base. The frame 1301 and the display unit 1302 may be curved.

The radius of curvature may be 5,000 mm or more and 6,000 mm or less.

FIG. 10B is a schematic view illustrating another example of the display apparatus according to the present embodiment. A display apparatus 1310 illustrated in FIG. 10B is configured to be foldable and is a so-called foldable display apparatus. The display apparatus 1310 has a first display unit 1311, a second display unit 1312, a housing 1313, and a folding point 1314. Each of the first display unit 1311 and the second display unit 1312 may include the light-emitting device according to the present embodiment. The first display unit 1311 and the second display unit 1312 may be a single display apparatus without a joint. The first display unit 1311 and the second display unit 1312 can be separated at the folding point. The first display unit 1311 and the second display unit 1312 may respectively display different images. Alternatively, a single image may be displayed on a set of the first and the second display units.

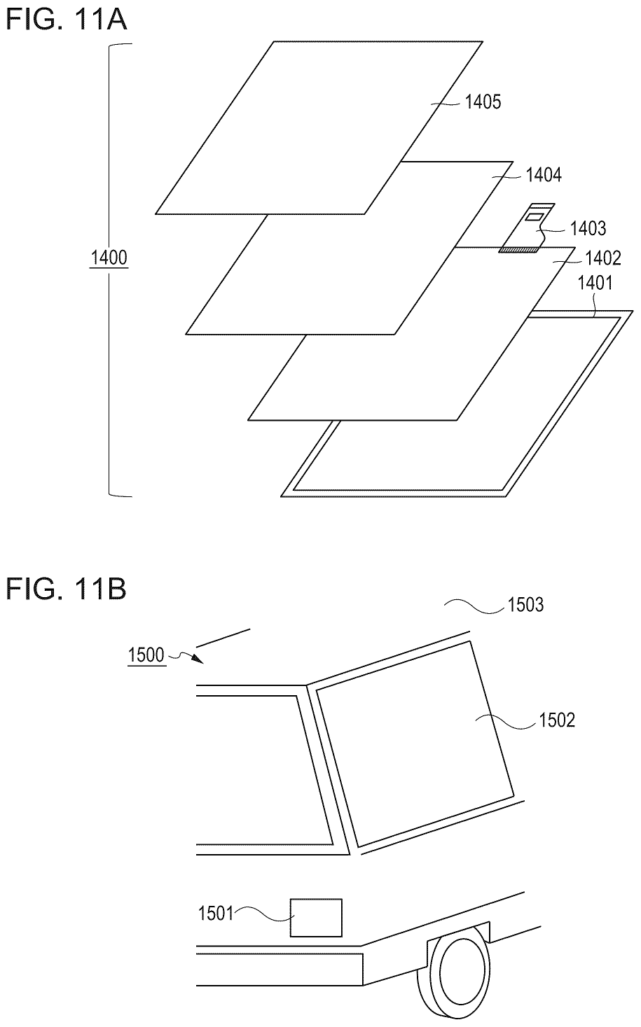

FIG. 11A is a schematic view illustrating an example of an illumination apparatus according to the present embodiment. An illumination apparatus 1400 may include a housing 1401, a light source 1402, a circuit substrate 1403, an optical filter 1404 and a light diffusion unit 1405 configured to transmit light emitted from the light source 1402. The light source 1402 may include the organic light-emitting device according to the present embodiment. The optical filter 1404 may be a filter that improves the color rendering properties of the light source. The light diffusion unit 1405 can effectively diffuse light emitted from the light source and allow the light to reach a wide range, for example, for lighting up. The optical filter 1404 and the light diffusion unit 1405 may be disposed on the light-emitting side of the illumination. A cover may be optionally disposed on the outermost portion.

The illumination apparatus is, for example, an apparatus that illuminates a room. The illumination apparatus may emit light of a color such as white, natural white, or any other color from blue to red. The illumination apparatus may have a light modulation circuit configured to modulate the light and a color control circuit configured to control the emission color. The illumination apparatus may include the organic light-emitting device of the present embodiment and a power supply circuit connected to the organic light-emitting device. The power supply circuit is a circuit configured to convert an AC voltage into a DC voltage. The illumination apparatus may have an inverter circuit. The white is a color having a color temperature of 4,200 K, and the natural white is a color having a color temperature of 5,000 K. The illumination apparatus may include a color filter.

The illumination apparatus according to the present embodiment may include a heat dissipation unit. The heat dissipation unit dissipates heat in the apparatus to the outside of the apparatus. The heat dissipation unit may be formed of, for example, a metal having a high specific heat or liquid silicone.

FIG. 11B is a schematic view of an automobile, which is an example of a moving object according to the present embodiment. The automobile has a tail lamp, which is an example of a lighting fixture. An automobile 1500 has a tail lamp 1501, and the tail lamp may light up when, for example, the brakes are applied.

The tail lamp 1501 may include the organic light-emitting device according to the present embodiment. The tail lamp 1501 may include a protective member that protects the organic light-emitting device. The protective member may be composed of any material that has high strength to a certain extent and is transparent, and can be composed of polycarbonate or the like. The polycarbonate may be mixed with a furandicarboxylic acid derivative, an acrylonitrile derivative, or the like.

The automobile 1500 may include a car body 1503 and a window 1502 attached to the car body 1503. The window 1502 may be a transparent display unless it is a window for checking the front and rear of the automobile. The transparent display may include the organic light-emitting device according to the present embodiment.

In such a case, the components, such as the electrodes, of the organic light-emitting device are formed of transparent members.

The moving object according to the present embodiment may be, for example, a ship, an aircraft, or a drone. The moving object may include a body and a lighting fixture attached to the body. The lighting fixture may emit light to indicate the position of the body. The lighting fixture includes the organic light-emitting device according to the present embodiment.

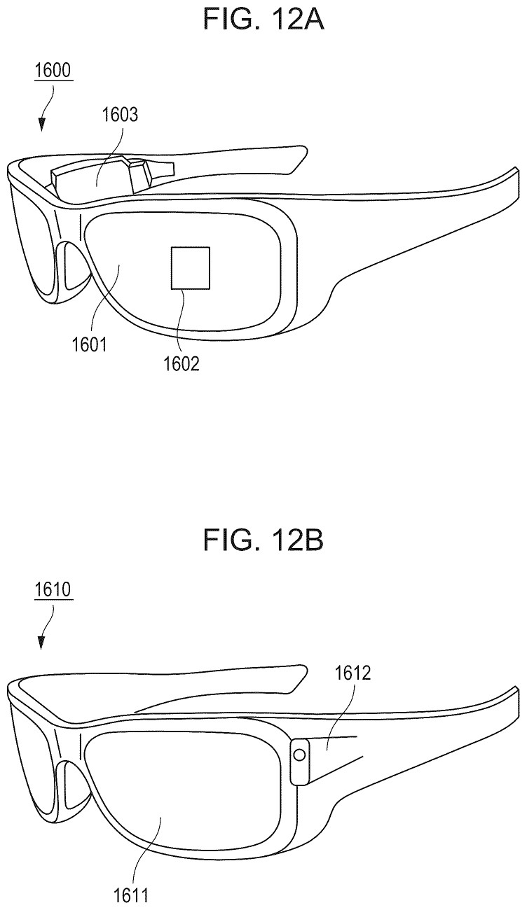

Examples of applications of the display apparatuses according to the embodiments described above will be described with reference to FIGS. 12A and 12B. The display apparatuses are applicable to systems that can be worn as wearable devices, such as smart glasses, head mount displays (HMDs), and smart contact lenses. An imaging and display apparatus used in such an example of the application includes an imaging apparatus that can perform photoelectric conversion of visible light and a display apparatus that can emit visible light.

FIG. 12A is a schematic view illustrating an example of a wearable device according to an embodiment of the present disclosure. Glasses 1600 (smart glasses) according to one example of applications will be described with reference to FIG. 12A. An imaging apparatus 1602 such as a complementary metal-oxide semiconductor (CMOS) sensor or a single-photon avalanche diode (SPAD) is disposed on a front side of a lens 1601 of the glasses 1600. The display apparatus according to any of the above-described embodiments is disposed on a back side of the lens 1601.

The glasses 1600 further include a control unit 1603. The control unit 1603 functions as a power supply that supplies electric power to the imaging apparatus 1602 and the display apparatus. The control unit 1603 controls the operation of the imaging apparatus 1602 and the display apparatus. An optical system for focusing light on the imaging apparatus 1602 is formed in the lens 1601.

FIG. 12B is a schematic view illustrating another example of the wearable device according to an embodiment of the present disclosure. Glasses 1610 (smart glasses) according to one example of applications will be described with reference to FIG. 12B. The glasses 1610 have a control unit 1612. The control unit 1612 includes an imaging apparatus corresponding to the imaging apparatus 1602 in FIG. 12A and a display apparatus. An optical system for projecting light emitted from the display apparatus and the imaging apparatus in the control unit 1612 is formed in a lens 1611, and an image is projected onto the lens 1611. The control unit 1612 functions as a power supply that supplies electric power to the imaging apparatus and the display apparatus and controls the operation of the imaging apparatus and the display apparatus.

The control unit 1612 may have a gaze detection unit configured to detect the gaze of the wearer. Infrared rays may be used to detect the gaze. An infrared light-emitting unit emits infrared light toward an eyeball of the user who is gazing at a displayed image. A captured image of the eyeball is obtained when an imaging unit including a light-receiving device detects reflection of the emitted infrared light from the eyeball. A reduction unit configured to reduce light from the infrared light-emitting unit to a display unit in plan view is provided to reduce degradation of the image quality. The gaze of the user with respect to the displayed image is detected from the captured image of the eyeball captured with the infrared light. Any publicly known method is applicable to the gaze detection using the captured image of the eyeball. As one example, a gaze detection method based on the Purkinje image formed by reflection of irradiation light on the cornea can be employed. More specifically, a gaze detection process based on a pupil-corneal reflection method is performed. The gaze of the user is detected using the pupil-corneal reflection method by calculating a gaze vector that indicates the direction (rotation angle) of the eyeball on the basis of the image of the pupil and the Purkinje image included in the captured image of the eyeball.

The display apparatus according to an embodiment of the present disclosure may include an imaging apparatus including a light-receiving device, and may control a displayed image of the display apparatus on the basis of the gaze information of the user from the imaging apparatus. Specifically, the display apparatus determines a first field-of-view region at which the user gazes and a second field-of-view region other than the first field-of-view region on the basis of the gaze information. The first field-of-view region and the second field-of-view region may be determined by the control unit of the display apparatus or may be determined by receiving those determined by an external control unit. In the display region of the display apparatus, the display resolution of the first field-of-view region may be controlled to be higher than the display resolution of the second field-of-view region. In other words, the resolution of the second field-of-view region may be lower than that of the first field-of-view region.

The display region includes a first display region and a second display region different from the first display region. A region with a higher priority is determined from the first display region and the second display region on the basis of the gaze information. The first display region and the second display region may be determined by the control unit of the display apparatus or may be determined by receiving those determined by an external control unit. The resolution of the region with a higher priority may be controlled to be higher than the resolution of the region other than the region with a higher priority. In other words, a region with a lower priority may have a lower resolution.

Artificial intelligence (AI) may be used to determine the first field-of-view region or the region with a higher priority. The AI may be a model configured to estimate the angle of the gaze and the distance to a target object at the end of the gaze from the image of the eyeball by using, as teaching data, the image of the eyeball and the direction in which the eyeball in the image was actually gazing. The AI program may be stored in the display apparatus, the imaging apparatus, or an external apparatus. When the AI program is stored in an external apparatus, the AI program is transmitted through communication to the display apparatus.

In the case of controlling the display on the basis of visual recognition detection, the display apparatus according to an embodiment of the present disclosure is applicable to smart glasses further including an imaging apparatus that captures an external image. The smart glasses can display the captured external information in real time.

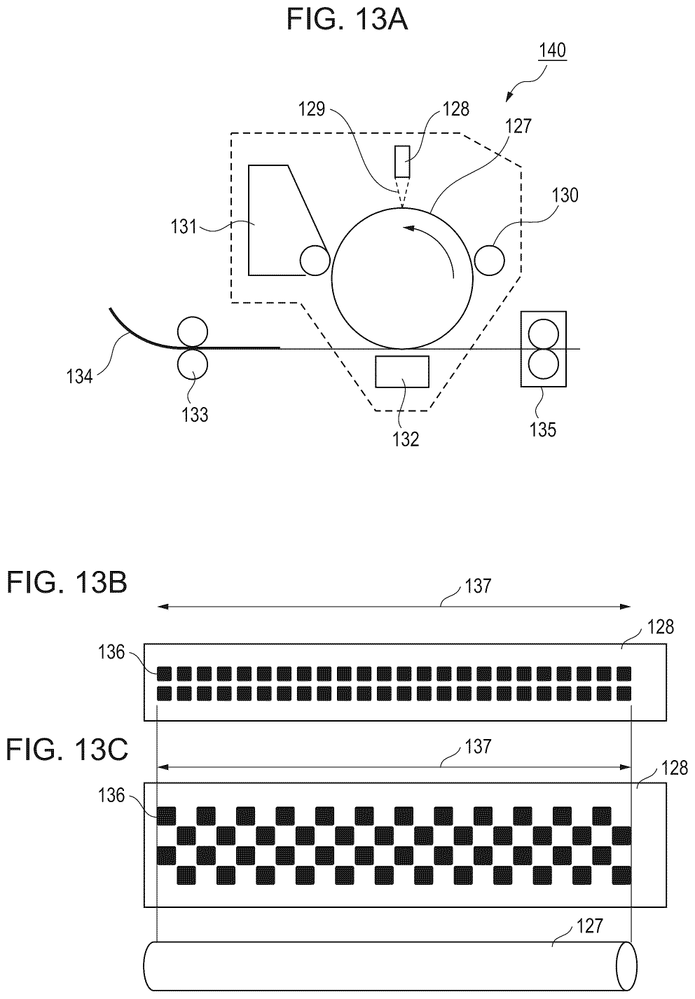

FIG. 13A is a schematic diagram illustrating an example of an image forming apparatus according to an embodiment of the present disclosure.

An image forming apparatus 140 is an electrophotographic image forming apparatus and includes a photoreceptor 127, an exposure light source 128, a charging portion 130, a developing portion 131, a transfer unit 132, transport rollers 133, and a fixing unit 135. Light 129 is applied from the exposure light source 128, and an electrostatic latent image is formed on the surface of the photoreceptor 127. The exposure light source 128 includes the organic light-emitting device according to the present embodiment. The developing portion 131 contains a toner and the like. The charging portion 130 charges the photoreceptor 127. The transfer unit 132 transfers a developed image to a recording medium 134. The transport rollers 133 transport the recording medium 134.

The recording medium 134 is, for example, paper. The fixing unit 135 fixes the image formed on the recording medium 134.

FIGS. 13B and 13C are views illustrating the exposure light source 128 and are schematic views illustrating a plurality of light-emitting portions 136 arranged on a long substrate. An arrow 137 indicates a direction parallel to the axis of the photoreceptor, that is, a row direction in which the organic light-emitting devices are arranged. The row direction is the same as the direction of the rotational axis of the photoreceptor 127. This direction can also be referred to as a major-axis direction of the photoreceptor 127. FIG. 13B illustrates a form in which the light-emitting portions 136 are arranged in the major-axis direction of the photoreceptor 127. FIG. 13C illustrates a form which is different from that in FIG. 13B and in which the light-emitting portions 136 are alternately arranged in the row direction in a first row and a second row. The first row and the second row are arranged at different positions in a column direction. In the first row, a plurality of light-emitting portions 136 are arranged at intervals. The second row has light-emitting portions 136 at positions corresponding to the spaces between the light-emitting portions 136 of the first row. In other words, the plurality of light-emitting portions 136 are also arranged at intervals in the column direction. The arrangement in FIG. 13C can also be referred to as, for example, a lattice arrangement, a staggered arrangement, or a checkered pattern.

As described above, the use of the organic light-emitting device according to the present embodiment enables a stable display for a long time with good image quality. Furthermore, the use of the organic light-emitting device according to the present embodiment enables both good outdoor visibility and power-saving display due to high-efficiency and high-luminance light output.

### EXAMPLES

### Example 1

An organic light-emitting device illustrated in FIGS. 1A and 1B was manufactured by the method illustrated in FIGS. 4A to 4D. First, a groove 10 (opening width w: 10 μm, depth d: 5 μm) having the cross-sectional shape illustrated in FIG. 3A was formed along the periphery of a display region 11 on a substrate 1 by photolithography using a gray scale mask. A lower electrode 3, a pixel isolation film 2, an organic compound layer 4, and an upper electrode 5 were formed on the substrate 1 in this order to form a plurality of organic light-emitting elements 6 in the display region 11.

Next, as illustrated in FIG. 4B, a first sealing layer 7 covering the organic light-emitting elements 6 was formed over the entire surface of the substrate 1 by a CVD method. The first sealing layer 7 was formed using silicon nitride with a moisture permeation rate of 10⁻⁵ g/m²/day or less to have a film thickness of 100 nm. A groove 10a was formed in the first sealing layer 7 at a position corresponding to the groove 10 of the substrate 1.

Next, as illustrated in FIG. 4C, a second sealing layer 8 was formed by patterning on the first sealing layer 7 using a shadow mask 20 illustrated in FIG. 5. As the second sealing layer 8, an aluminum oxide film was formed to have a film thickness of 10 nm by an ALD method. The ALD method allows conformal deposition in a highly uneven structure having an aspect ratio of higher than 1/10. Specifically, as illustrated in FIG. 4C, the shadow mask 20 was disposed such that an edge portion 22 constituting the periphery of an opening 21 was located on the groove 10a of the first sealing layer 7. Subsequently, the second sealing layer 8 was formed in the opening 21 of the shadow mask 20. An edge portion of the second sealing layer 8 was formed on an inner portion of the groove 10a of the first sealing layer 7.

Next, as illustrated in FIG. 4D, after the shadow mask 20 was removed, a third sealing layer 9 was formed by a CVD method over the entire surface of the substrate 1 so as to cover the first sealing layer 7 and the second sealing layer 8. The third sealing layer 9 was formed using silicon nitride with a moisture permeation rate of 10⁻⁵ g/m²/day or less to have a film thickness of 100 nm. As illustrated in FIG. 4D, a concave portion was formed in the third sealing layer 9 at a position corresponding to the groove 10 of the substrate 1.

The prepared organic light-emitting device was stored in a high-temperature, high-humidity (60° C./90%) testing apparatus, and non-light-emission defects of the organic light-emitting device after storage for 100 hours, after storage for 200 hours, after storage for 1,000 hours, and after storage for 2,000 hours were evaluated in accordance with the following criteria. Note that the evaluation was discontinued at the time when non-light-emission defects were generated. The results are shown in Table 1.
A: Non-light-emission defects were not generated in the light-emitting region.
B: Although non-light-emission defects were generated in the light-emitting region, specifications of the organic light-emitting device were satisfied.
C: Non-light-emission defects were generated in the light-emitting region, and specifications of the organic light-emitting device were not satisfied.

### Examples 2 to 7

Organic light-emitting devices were manufactured and evaluated as in Example 1 except that the cross-sectional shape of the groove 10 was changed as shown in Table 1. The results are shown in Table 1.

In the groove (FIG. 3D) of Example 4, the position of the deepest portion is shifted by 2 μm from the center of the groove 10 in the width direction to the outside. In the groove (FIG. 3E) of Example 5, the position of the deepest portion is shifted by 2 μm from the center of the groove 10 in the width direction to the inside. In the groove (FIG. 3F) of Example 6, the outside is 3 μm lower than the inside. In the groove (FIG. 3G) of Example 7, the outside is 2 μm higher than the inside.

### Comparative Example 1

An organic light-emitting device was manufactured and evaluated as in Example 1 except that the groove 10 was not provided on the substrate 1. The results are shown in Table 1.

### Examples 8 and 9

Organic light-emitting devices were manufactured and evaluated as in Example 1 except that the moisture permeation rate of the first sealing layer 7 or the third sealing layer 9 was changed as shown in Table 1. The results are shown in Table 1.

### Example 10

An organic light-emitting device was manufactured and evaluated as in Example 1 except that the second sealing layer 8 was formed using a material that could be conformally deposited in a structure having an aspect ratio of 1/10.

The results are shown in Table 1.

TABLE 1

| | | | | First sealing | | Third sealing | | | | |
|---|---|---|---|---|---|---|---|---|---|---|
| | | | | layer | | layer | | | | |
| | | | | Moisture | Second | Moisture | Storage time | | | |
| | Groove | w | d | permeation rate | sealing layer | permeation rate | [hour] | | | |
| | Shape | [μm] | | [g/m²/day] | Aspect ratio | [g/m²/day] | 100 | 200 | 1000 | 2000 |
| Example 1 | FIG. 3A | 10 | 5 | 10⁻⁵ or less | Higher than | 10⁻⁵ or less | A | A | A | A |
| | | | | | 1/10 | | | | | |
| Example 2 | FIG. 3B | 10 | 5 | 10⁻⁵ or less | Higher than | 10⁻⁵ or less | A | A | A | A |
| | | | | | 1/10 | | | | | |
| Example 3 | FIG. 3C | 10 | 5 | 10⁻⁵ or less | Higher than | 10⁻⁵ or less | A | A | A | A |
| | | | | | 1/10 | | | | | |
| Example 4 | FIG. 3D | 10 | 5 | 10⁻⁵ or less | Higher than | 10⁻⁵ or less | A | A | A | A |
| | | | | | 1/10 | | | | | |
| Example 5 | FIG. 3E | 10 | 5 | 10⁻⁵ or less | Higher than | 10⁻⁵ or less | A | A | A | A |
| | | | | | 1/10 | | | | | |
| Example 6 | FIG. 3F | 10 | 5 | 10⁻⁵ or less | Higher than | 10⁻⁵ or less | A | A | A | A |
| | | | | | 1/10 | | | | | |
| Example 7 | FIG. 3G | 10 | 5 | 10⁻⁵ or less | Higher than | 10⁻⁵ or less | A | A | A | A |
| | | | | | 1/10 | | | | | |
| Example 8 | FIG. 3A | 10 | 5 | 7 × 10⁻⁴ | Higher than | 10⁻⁵ or less | A | A | B | C |
| | | | | | 1/10 | | | | | |
| Example 9 | FIG. 3A | 10 | 5 | 10⁻⁵ or less | Higher than | 7 × 10⁻⁴ | A | B | B | C |
| | | | | | 1/10 | | | | | |
| Example 10 | FIG. 3A | 10 | 5 | 10⁻⁵ or less | 1/10 | 10⁻⁵ or less | A | B | B | C |
| Comparative | — | — | — | 10⁻⁵ or less | Higher than | 10⁻⁵ or less | C | — | — | — |
| Example 1 | | | | | 1/10 | | | | | |

The present disclosure can provide an organic light-emitting device that has good water resistance and that can have a narrow frame and a method for manufacturing the organic light-emitting device.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-038937 filed Mar. 13, 2024, which is hereby incorporated by reference herein in its entirety.

What is claimed is:

1. A method for manufacturing an organic light-emitting device, the method comprising:
an organic light-emitting element forming step of forming a plurality of organic light-emitting elements on a substrate;
a first sealing layer forming step of forming a first sealing layer covering the organic light-emitting elements and having a groove in a non-display region; and
a second sealing layer forming step of forming a second sealing layer on the first sealing layer using a shadow mask,
wherein the second sealing layer forming step is a step of forming the second sealing layer in a state where an edge portion constituting a periphery of an opening of the shadow mask is disposed so as to be located on the groove.

2. The method for manufacturing an organic light-emitting device according to claim 1, further comprising:
a third sealing layer forming step of, after removing the shadow mask, forming a third sealing layer covering the second sealing layer.

3. The method for manufacturing an organic light-emitting device according to claim 1, wherein the first sealing layer has a moisture permeation rate of 10⁻⁵ g/m²/day or less.

4. The method for manufacturing an organic light-emitting device according to claim 1, wherein the second sealing layer is a layer capable of being conformally deposited in a structure having an aspect ratio of higher than 1/10.

5. The method for manufacturing an organic light-emitting device according to claim 1, further comprising:
a substrate groove forming step of forming a groove in the non-display region of the substrate,
wherein the groove of the first sealing layer is formed along the groove in the substrate.

6. The method for manufacturing an organic light-emitting device according to claim 5, wherein the substrate groove forming step is a step of forming the groove along a periphery of a display region of the substrate.

7. The method for manufacturing an organic light-emitting device according to claim 1, wherein the first sealing layer forming step is a step of forming the first sealing layer over an entire surface of the substrate.

8. The method for manufacturing an organic light-emitting device according to claim 2, wherein the third sealing layer has a moisture permeation rate of 10⁻⁵ g/m²/day or less.

9. The method for manufacturing an organic light-emitting device according to claim 2, wherein the third sealing layer forming step is a step of forming the third sealing layer over an entire surface of the substrate.

10. An organic light-emitting device comprising:
a substrate;
a plurality of organic light-emitting elements; and
a sealing layer covering the organic light-emitting elements, the organic light-emitting elements and the sealing layer being disposed on the substrate,
wherein the sealing layer includes a first sealing layer and a second sealing layer covering the first sealing layer,
the first sealing layer has a groove in a non-display region, and
an edge portion of the second sealing layer is formed on an inner portion of the groove.

11. The organic light-emitting device according to claim 10, wherein the sealing layer further includes a third sealing layer covering the second sealing layer.

12. The organic light-emitting device according to claim 10, wherein the first sealing layer has a moisture permeation rate of 10⁻⁵ g/m²/day or less.

13. The organic light-emitting device according to claim 10, wherein the second sealing layer is a layer capable of being conformally deposited in a structure having an aspect ratio of higher than 1/10.

14. The organic light-emitting device according to claim 10, wherein a groove is provided in the non-display region of the substrate, and the groove of the first sealing layer is formed along the groove in the substrate.

15. The organic light-emitting device according to claim 14, wherein the groove in the substrate is formed along a periphery of a display region of the substrate.

16. The organic light-emitting device according to claim 10, wherein the first sealing layer is formed over an entire surface of the substrate.

17. The organic light-emitting device according to claim 11, wherein the third sealing layer is formed over an entire surface of the substrate.

18. A display apparatus comprising:
the organic light-emitting device according to claim 10,
wherein the organic light-emitting device includes a plurality of pixels, and
at least one of the plurality of pixels includes an organic light-emitting element and a transistor connected to the organic light-emitting element.

19. A photoelectric conversion apparatus comprising:
an optical unit including a plurality of lenses;
an imaging device configured to receive light that has passed through the optical unit; and
a display unit configured to display an image captured by the imaging device,
wherein the display unit includes the organic light-emitting device according to claim 10.

20. An illumination apparatus comprising:
a light source including the organic light-emitting device according to claim 10; and
a light diffusion unit or an optical filter configured to transmit light emitted from the light source.
